(19) United States
(12) Patent Application Publication
(10) Pub. No.: US 2016/0163370 A1
(43) Pub. Date: Jun. 9, 2016

(54) MEMORY DEVICE

(71) Applicant: KABUSHIKI KAISHA TOSHIBA, Tokyo (JP)

(72) Inventors: Mikio MIYATA, Yokohama Kanagawa (JP); Katsuhiko HOYA, Yokohama Kanagawa (JP)

(73) Assignee: KABUSHIKI KAISHA TOSHIBA, Tokyo (JP)

(21) Appl. No.: 14/638,671

(22) Filed: Mar. 4, 2015

Related U.S. Application Data
(60) Provisional application No. 62/089,550, filed on Dec. 9, 2014.

(51) Int. Cl. G11C 11/16; G11C 29/00; G11C 17/16

(52) U.S. Cl. CPC G11C 11/1675; G11C 11/161; G11C 11/1653; G11C 17/16; G11C 29/78

(57) ABSTRACT

According to one embodiment, a memory device includes a first memory element being able to store data, and a second memory element storing information relating to the first memory element, wherein the information of the second memory element is rewritten by a power amount, which is greater than a power amount at a time when the data is written in the first memory element, being supplied to the second memory element.

### CROSS REFERENCE TO RELATED APPLICATIONS

This application claims the benefit of U.S. Provisional Application No. 62/089,550, filed Dec. 9, 2014, the entire contents of which are incorporated herein by reference.

### FIELD

Embodiments described herein relate generally to a memory device.

### BACKGROUND

As a memory device, for instance, an MRAM using a magnetoresistive effect element is known.

### BRIEF DESCRIPTION OF THE DRAWINGS

FIG. 1 illustrates an example of a circuit configuration of a memory device according to an embodiment.

FIG. 2 schematically illustrates a configuration example of a memory element which the memory device according to the embodiment includes.

FIG. 3 schematically illustrates a configuration example of a memory element which the memory device according to the embodiment includes.

FIG. 4 illustrates an example of conditions of write to the memory elements which the memory device according to the embodiment includes.

FIG. 5 illustrates a configuration example of a mode controller which the memory device according to the embodiment includes, and circumjacent circuits thereof.

FIG. 6 illustrates a flow of a write operation to a fuse cell which the memory device according to the embodiment includes.

### DETAILED DESCRIPTION

According to an embodiment to be described below, a memory device, which can rewrite information of a fuse circuit, is provided. Specifically, a memory device of an embodiment includes a first memory element being able to store data, and a second memory element storing information relating to the first memory element. The information is rewritten by a power amount, which is greater than a power amount at a time when the data is written in the first memory element, being supplied to the second memory element.

The embodiments will be described hereinafter with reference to the accompanying drawings. In the drawings, the same parts are denoted by the same reference numerals. In addition, an overlapping description will be given where necessary. The memory device according to the embodiments is, for instance, an STT (Spin-Transfer Torque)-type MRAM (Magnetoresistive Random Access Memory) using a magnetoresistive effect element as a memory element. As the magnetoresistive effect element, for example, an MTJ (Magnetic Tunnel Junction) element is used.

### EMBODIMENT

A memory device according to an embodiment is described below.

### (1) Configuration Example of Memory Device

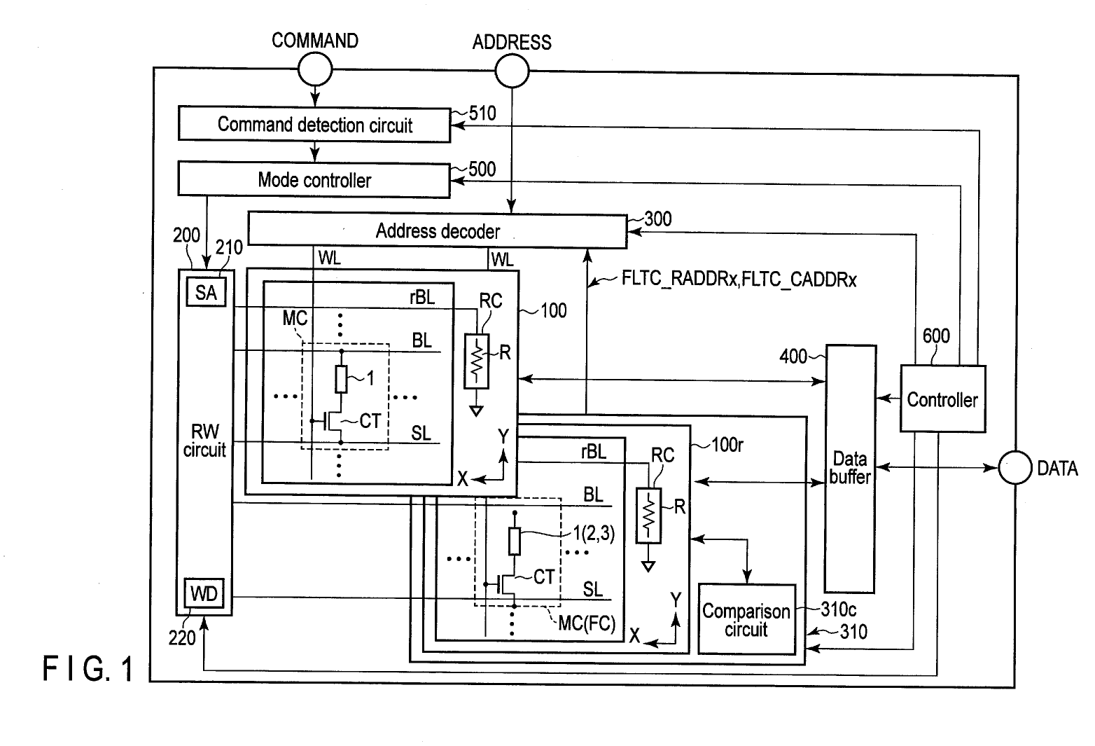

Referring to FIG. 1, a description is given of a configuration example of an MRAM 10 functioning as the memory device according to this embodiment. FIG. 1 illustrates an example of a circuit configuration of the memory device according to the embodiment.

As illustrated in FIG. 1, the MRAM 10 includes a cell array 100, a read/write circuit (RW circuit) 200, an address decoder 300, a fuse information memory circuit 310, a data buffer 400, a mode controller 500, a command detection circuit 510, and a controller 600.

[Cell Array]

The cell array 100 includes a plurality of memory cells MC and a plurality of reference cells RC. The cell array 100 also includes a plurality of bit lines BL extending in an X direction (column direction) and a plurality of source lines SL which are paired with these bit lines BL. The cell array 100 further includes a plurality of word lines WL extending in a Y direction (row direction).

The plural memory cells MC are arranged in a matrix within the cell array 100. Plural memory cells MC, which are arranged in the X direction (column direction), are connected to the paired common bit line BL and source line SL. Plural memory cells MC, which are arranged in the Y direction (row direction), are connected to the common word line WL.

Each memory cell MC includes, for example, an MTJ element 1 functioning as a first memory element (first magnetoresistive effect element), and a cell transistor CT. The MTJ element 1 can take, for example, a high-resistance state or a low-resistance state. The MTJ element 1 can store data by a change of such resistance states. The MTJ element 1 is configured such that data is written in, and is read out of, the MTJ element 1 by various currents being supplied to the MTJ element 1. Data write and data read for the MTJ element 1 are executed by, for example, a user of the MRAM 10, as needed. The data, which is stored in the MTJ element 1, is also called “user data”. The cell transistor CT is connected in series to the MTJ element 1, and is configured to control the supply and stop of current to the MTJ element 1. The supply of current is started by turn-on of the cell transistor CT, and the supply of current is stopped by turn-off of the cell transistor CT.

The memory cell MC is connected, at one end of the MTJ element 1, to one of the paired bit line BL and source line SL, for example, the bit line BL. In addition, the memory cell MC is connected, at one end of the current path of the cell transistor CT, to the other of the paired bit line BL and source line SL, for example, the source line SL. Furthermore, the memory cell MC is connected to the word line WL at the gate of the cell transistor CT.

Each reference cell RC is connected to a bit line rBL for reference cell RC, and is used at a time of read of that memory cell MC of the plural memory cells MC, which is associated with this reference cell RC itself. The reference cell RC includes one or more resistor elements R. The resistor elements R have a resistance value of an intermediate magnitude (hereinafter, also referred to as “intermediate resistance value”) between a resistance value of the MTJ element 1 in the high-resistance state and a resistance value of the MTJ element 1 in the low-resistance state. Using the reference cell RC, a reference current is generated which becomes a determination reference for read of data that the memory cell MC stores.

[Fuse Information Memory Circuit]

The fuse information memory circuit 310 includes a redundant cell array 100r and a comparison circuit 310c.

The redundant cell array 100r includes the same configuration as the cell array 100, and the cell array 100 and redundant cell array 100r can be replaced with each other. Specifically, the redundant cell array 100r includes memory cells MC each including an MTJ element 1 and a cell transistor CT, reference cells RC, and various wiring lines BL, SL, WL. When a memory cell MC of the cell array 100 has a defect or the like, this memory cell MC is replaced with a memory cell MC of the redundant cell array 100r.

The redundant cell array 100r also includes a plurality of fuse cells FC, and reference cells RC which are associated with these fuse cells FC. Each fuse cell FC includes the same configuration as the memory cell MC. Specifically, the fuse cell FC includes either an MTJ element 2 or 3, which functions as a second memory element, and a cell transistor CT, and is connected to various wiring lines BL, SL and WL. The MTJ element 2 functioning as a second magnetoresistive effect element has a low resistance. The MTJ element 3 functioning as a third magnetoresistive effect element has a high resistance.

A fuse circuit is constituted by, mainly, the plural fuse cells FC, the reference cells RC associated with these fuse cells FC, the various wiring lines BL, SL and WL, and the comparison circuit 310c.

The fuse circuit stores information relating to the memory cells MC of the cell array 100 by the combination of the MTJ elements 2 and 3 of the plural fuse cells FC. This information is, for example, information such as an address FLTC_CADDRx of a memory cell MC with a defect of the memory cells MC of the cell array 100, and an address FLTC_RADDRx of a memory cell MC of the redundant cell array 100r, with which the memory cell MC with the defect is replaced. In this manner, the information stored in the MTJ elements 2, 3 is, for instance, system data relating to specifications of the MRAM 10. Unlike the above-described user data, the information stored in the MTJ elements 2, 3 is not designed for, for example, frequent rewrite by the user. However, in the present embodiment, as will be described later, by supplying to the fuse cell FC a power amount which is greater than a power amount for data write to the memory cell MC, rewrite of information for the fuse cell FC is enabled.

The fuse information memory circuit 310 receives address information from an outside from the address decoder 300 at a write time and a read time for the memory cell MC. The comparison circuit 310c compares such address information with the address information of the defective memory cell MC, which is stored in the fuse circuit. If both address information pieces agree, the comparison circuit 310c acquires from the fuse circuit the address information of the memory cell MC of the redundant cell array 100r, which is a replacement target, and transfers this address information to the address decoder 300. If both address information pieces do not agree, the comparison circuit 310c returns the address information from the outside to the address decoder 300 as such.

[Address Decoder, and RW Circuit]

The address decoder 300 is connected to one end of each of word lines WL extending from the cell array 100 and redundant cell array 100r. The address decoder 300 controls activation and deactivation of each word line WL, based on the address information from the outside and the above-described replaced address information. Thereby, the memory cell MC of the cell array 100 or the redundant cell array 100r is properly selected. When the information of the fuse cell FC is to be rewritten, the address decoder 300 selects a fuse cell FC which is a target of rewrite, based on address information from the outside.

The RW circuit 200 is connected to the bit lines BL, BLr and source lines SL extending from the cell array 100 and redundant cell array 100r. The RW circuit 200 includes a sense amplifier 210, a write driver 220, and a write controller (not shown), and executes a write operation and a read operation in accordance with the control of the controller 600.

The write driver 220 is connected to each of the paired bit line BL and source line SL. The write driver 220 supplies a write current to the memory cell MC that is a target of write, at a time of data write. By the supply of the write current, the resistance state (resistance value) of the MTJ element 1 of the target memory cell MC changes. When the information of the fuse cell FC is to be rewritten, the write driver 220 supplies a write current to the fuse cell FC.

The write controller generates a write current. As described above, when the information of the fuse cell FC is to be rewritten, a power amount, which is greater than a power amount for data write to the memory cell MC, is generated by the write controller. The configuration of the write controller will be described later.

The sense amplifier 210 is connected to each of bit lines BL, BLr. The sense amplifier 210 detects the value of a read current or the potential of the bit line BL, and compares this value or potential with a reference current generated by using the reference cell RC. Thereby, the data stored in the memory cell MC is read out. Similarly, the sense amplifier 210 reads out the information stored in the fuse cell FC.

[Mode Controller, and Command Detection Circuit]

The mode controller 500 controls switching of the mode of a write operation for the memory cell MC or a rewrite operation of the fuse cell FC. At that time, the mode controller 500 switches the write conditions (write mode) in accordance with a command from an outside, which was detected by the command detection circuit 510. Thereby, a different power amount is supplied in accordance with a difference of an operation target which is the memory cell MC or the fuse cell FC, and the write operation for the memory cell MC or the rewrite operation of the fuse cell FC is executed.

The above-described fuse circuit may further include the mode controller 500 and RW circuit 200. A detailed configuration of circumjacent circuits including the mode controller 500 and RW circuit 200 will be described later.

[Data Buffer and Controller]

The data buffer 400 temporarily stores data which is to be written in the cell array 100, or data which has been read out of the cell array 100. In addition, the data buffer 400 temporarily stores data which is to be written in the redundant cell array 100r, or data which has been read out of the redundant cell array 100r.

The controller 600 is connected to the RW circuit 200, address decoder 300, fuse information memory circuit 310, data buffer 400, mode controller 500, and command detection circuit 510. In accordance with signals received from the outside, the controller 600 controls the RW circuit 200, address decoder 300, fuse information memory circuit 310, data buffer 400, mode controller 500, and command detection circuit 510.

### (2) Configuration Examples of Magnetoresistive Effect Element

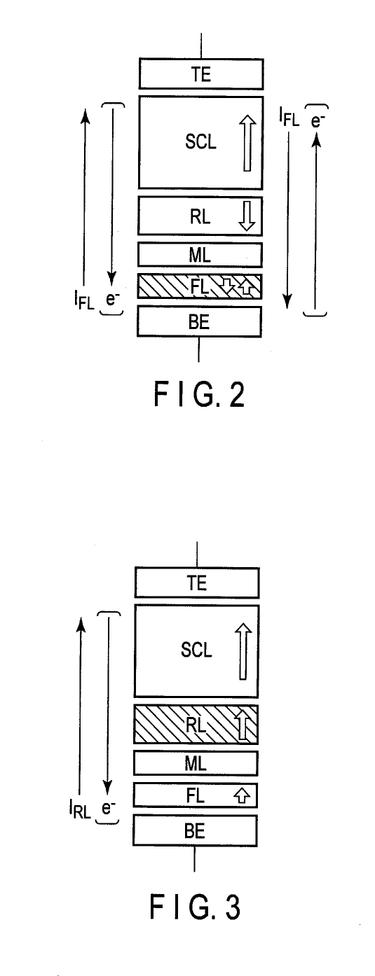

Referring to FIG. 2 and FIG. 3, configuration examples of the MTJ elements 1, 2 and 3 are described. FIG. 2 and FIG. 3 schematically illustrate examples of the memory element which the memory device according to the embodiment includes.

[First Magnetoresistive Effect Element]

An MTJ element 1 illustrated in FIG. 2 functions as a memory element which can store (user) data. The MTJ element 1 is configured to take a different resistance state in accordance with the direction of a current flowing through the MTJ element 1. A phenomenon in which a different resistance is exhibited in accordance with a state is called “magnetoresistive effect”. The MTJ element 1 stores data by using the magnetoresistive effect.

As illustrated in FIG. 2, the MTJ element 1 includes, at least, a memory layer (free layer) FL provided on a bottom electrode BE, a reference layer RL provided on the memory layer FL, and a shift cancel layer (shift control layer) SCL provided on the reference layer RL. A top electrode TE is provided on the shift cancel layer SCL. A middle layer ML is included between the memory layer FL and reference layer RL. The memory layer FL, middle layer ML and reference layer RL constitute a magnetic tunnel junction.

The memory layer FL, reference layer RL and shift cancel layer SCL are magnetic layers having a magnetic anisotropy. The memory layer FL, reference layer RL and shift cancel layer SCL have the magnetic anisotropy in, for example, a direction crossing layer surfaces thereof. The layer surface is a surface at which a certain layer faces another layer. The direction crossing the layer surface is a direction perpendicular to, or substantially perpendicular to, the layer surface. Specifically, the MTJ element 1 is configured, for example, as a vertical magnetization MTJ element having a vertical magnetic anisotropy.

The memory layer FL has a magnetization direction toward the bottom electrode BE side or the reference layer RL side, and this magnetization direction is easily reversed. The reference layer RL has a magnetization direction toward the memory layer FL side. The shift cancel layer SCL has a magnetization direction toward the top electrode TE side. Specifically, the shift cancel layer SCL has a magnetization direction which is antiparallel to the magnetization direction of the reference layer RL, and functions to prevent reversal of the magnetization direction of the reference layer RL. In the range of usual use of the MTJ element 1, the magnetization directions of the reference layer RL and shift cancel layer SCL are fixed.

The ease in reversal of the magnetization direction of each layer FL, RL, SCL is determined by the coercivity that each layer FL, RL, SCL has. The coercivity is a property of retention of magnetism. As the coercivity is greater, the magnetism is retained more easily and the reversal of the magnetization direction becomes more difficult. The memory layer FL has a first coercivity. The reference layer RL has a second coercivity which is greater than the first coercivity. The shift cancel layer SCL has a third coercivity which is greater than the second coercivity. Specifically, of the respective layers FL, RL and SCL, the memory layer FL has a smallest coercivity, and the magnetization direction thereof is reversed most easily.

The reference layer RL and shift cancel layer SCL have greater coercivities than the memory layer FL, and it is difficult to reverse their magnetization directions.

Such coercivity is determined by, for example, the thickness of each of the layer FL, RL and SCL, that is, the width in the direction of stacking of these layers. The thicker the layer, the greater the coercivity. For example, the reference layer RL is thicker than the memory layer FL, and the shift cancel layer SCL is thicker than the reference layer RL.

The ease in reversal of the magnetization direction of each layer FL, RL, SCL can also explained by the magnitude of a magnetization reversal threshold value that each layer FL, RL, SCL has. The magnetization reversal threshold value is a current value at a time of reversal of the magnetization direction in each layer FL, RL, SCL, when a current flowing through the MTJ element 1 has been supplied in such a direction that the magnetization direction of each layer FL, RL, SCL is reversed. At a current value of less than the magnetization reversal threshold value, the magnetization direction of each layer FL, RL, SCL is not reversed. At a current value of the magnetization reversal threshold value or more, the magnetization direction of each layer FL, RL, SCL is reversed. Of the respective layers FL, RL and SCL, the memory layer FL has a lowest magnetization reversal threshold value, and the magnetization direction of the memory layer FL is easily reversed at a small current value. The shift cancel layer SCL has a highest magnetization reversal threshold value, and the magnetization direction of the shift cancel layer SCL is not reversed unless the current value is large. The reference layer RL has a magnetization reversal threshold value between the magnetization reversal threshold value of the memory layer FL and the magnetization reversal threshold value of the shift cancel layer SCL.

From the above, the memory layer FL is configured as a layer of a write target, the magnetization direction of which is maintained or reversed in accordance with the direction of a write current I_{FL} which is supplied at a time of write. The write current I_{FL} has such a magnitude as to reverse the magnetization direction of the memory layer FL, but not to reverse the magnetization direction of each of the reference layer RL and the shift cancel layer SCL. Specifically, the write current I_{FL} is, for example, larger than the magnetization reversal threshold value of the memory layer FL, and is smaller than the magnetization reversal threshold value of each of the reference layer RL and the shift cancel layer SCL.

For example, if the write current I_{FL} is caused to flow from the memory layer FL toward the reference layer RL, the magnetization directions of the memory layer FL and reference layer RL become parallel to each other.

In this case, electrons flow from the reference layer RL toward the memory layer FL. Of the electrons which have passed through the reference layer RL, electrons, which are spin-polarized in the same direction as the magnetization direction of the reference layer RL, become dominant. A spin angular momentum amount of these electrons is transmitted to the magnetic field of the memory layer FL having a less coercivity than the reference layer RL. Thereby, the magnetization direction of the memory layer FL is stabilized so as to become identical to the magnetization direction of the reference layer RL.

Conversely, if the write current I_{FL} is caused to flow from the reference layer RL toward the memory layer FL, the magnetization directions of the memory layer FL and reference layer RL become antiparallel to each other.

In this case, electrons flow from the memory layer FL toward the reference layer RL. Of the electrons which have passed through the memory layer FL, electrons, which are spin-polarized in a direction opposite to the magnetization direction of the reference layer RL, are reflected by the reference layer RL having a greater coercivity than the memory layer FL. The reflected electrons are injected in the memory layer FL, and a spin angular momentum amount of these electrons is transmitted to the magnetic field of the memory layer FL. Thereby, the magnetization direction of the memory layer FL is stabilized so as to become opposite to the magnetization direction of the reference layer RL.

The MTJ element 1 exhibits a different resistance state in accordance with the relative relationship between the magnetization direction of the reference layer RL and the magnetization direction of the memory layer FL. Specifically, the MTJ element 1 is configured to store data of “1” or “0”, according to whether the magnetization directions of the reference layer RL and memory layer FL are in a parallel state (low-resistance state) or in an antiparallel state (high-resistance state). Either the parallel state (low-resistance state) or the antiparallel state (high-resistance state) may arbitrarily be set at “1” data or “0” data. The “1” data and “0” data are distinguished by comparing the magnitude of a read current flowing in the MTJ element 1 and the magnitude of a reference current flowing in the reference cell RC.

[Second and Third Magnetoresistive Effect Elements]

The MTJ element 3 functions as a memory element which stores a high-resistance state. The MTJ element 3 includes the same configuration as the above-described MTJ element 1 of FIG. 2, and the magnetization direction of the memory layer FL is antiparallel to the magnetization direction of the reference layer RL. The state of this MTJ element 3 is the initial state of the fuse cell FC. Specifically, in the fuse circuit, all fuse cells FC before program of address information relating to memory cells MC, etc. include MTJ elements 3.

The MTJ element 2 functions as a memory element which stores a low-resistance state. The MTJ element 2 includes substantially the same configuration as the above-described MTJ element 1 of FIG. 2, but the magnetization direction of the reference layer RL is parallel to the magnetization direction of the shift cancel layer SCL. Thereby, no matter how the magnetization direction of the memory layer FL is set, the MTJ element 2 exhibits low resistance. The reason for this is that since both the reference layer RL and the shift cancel layer SCL have the identical magnetization direction, an extremely stronger magnetic field than the magnetic field of the memory layer FL is generated, so that the magnetization direction of the memory layer FL can take only such a state as to be parallel to the magnetization direction of each of the reference layer RL and shift cancel layer SCL. Thus, for example, even if write is so executed that the magnetization direction of the memory layer FL may become antiparallel to the magnetization direction of each of these layers RL and SCL, the magnetization direction of the memory layer FL is stabilized so as to become parallel to the magnetization direction of each of these layers RL and SCL.

This MTJ element 2 can be obtained by reversing the magnetization direction of the reference layer RL of the MTJ element 3. In order to reverse the magnetization direction of the reference layer RL, for example, a write current I_{RL}, which is greater than the above-described write current I_{FL} for reversing the magnetization direction of the memory layer FL, is used. The write current I_{RL} has such a magnitude as to reverse the magnetization direction of the reference layer RL. Specifically, the write current I_{RL} is greater than, for example, the magnetization reversal threshold value of the reference layer RL. More preferably, the write current I_{RL} has such a magnitude as to reverse the magnetization direction of the reference layer RL, but not to reverse the magnetization direction of the shift cancel layer SCL. Specifically, the write current I_{RL} is greater than the magnetization reversal threshold value of the reference layer RL and is less than the magnetization reversal threshold value of the shift cancel layer SCL.

For example, if the write current I_{RL} is caused to flow from the reference layer RL toward the shift cancel layer SCL, the magnetization directions of the reference layer RL and the shift cancel layer SCL become parallel to each other.

The mechanism in this case is the same as in the above-described case in which the magnetization directions of the the memory layer FL and reference layer RL become parallel. Specifically, a spin angular momentum amount of the electrons, which are spin-polarized in the same direction as the magnetization direction of the shift cancel layer SCL, is transmitted to the magnetic field of the reference layer RL having a less coercivity than the shift cancel layer SCL. Thereby, the magnetization direction of the reference layer RL is stabilized so as to become identical to the magnetization direction of the shift cancel layer SCL.

In order to restore the magnetization directions of the reference layer RL and shift cancel layer SCL to the antiparallel state, the write current I_{RL} may be caused to flow in a direction reverse to the above, that is, in a direction from the shift cancel layer SCL toward the reference layer RL.

The mechanism in this case is the same as in the above-described case in which the magnetization directions of the the memory layer FL and reference layer RL become antiparallel. Specifically, a spin angular momentum amount of the electrons, which are spin-polarized in the direction opposite to the magnetization direction of the shift cancel layer SCL, is transmitted to the magnetic field of the reference layer RL having a less coercivity than the shift cancel layer SCL. Thereby, the magnetization direction of the reference layer RL is stabilized so as to become opposite to the magnetization direction of the shift cancel layer SCL.

In this manner, in the fuse circuit, the fuse cell FC including the high-resistance MTJ element 3 is in the initial state. A certain fuse cell FC is rewritten to the low-resistance MTJ element 2, where necessary, and thereby address information, etc. of a memory cell MC with a defect is stored. In addition, the individual fuse cells FC are configured to be able to rewrite the once stored address information, etc., by being supplied with a write current I_{RL} which is greater than the write current I_{FL}. At a time of reading out such information, the read current flowing in these fuse cells FC is compared with the reference current flowing in the reference cells RC which are associated with the fuse cells FC. If the read current flowing in a certain fuse cell FC is less than the reference current, it is determined that this fuse cell FC is in the high-resistance state. If the read current flowing in a certain fuse cell FC is greater than the reference current, it is determined that this fuse cell FC is in the low-resistance state.

In addition, as described above, the write to the fuse cell FC means write for reversing the magnetization direction of the reference layer RL. Such write includes write to a fuse cell FC which is in the initial state, and rewrite of information of a fuse cell FC in which information relating to a memory cell MC has already been written. In particular, the write and rewrite to the MTJ element 2 in the low-resistance state, that is, the write for making the magnetization direction of the reference layer RL parallel to the magnetization direction of the shift cancel layer SCL, is also referred to as “P_stuck write” in the present specification. The above-described write current I_{RL} of the MTJ element 2, 3 is the current for reversing the magnetization direction of the reference layer RL.

However, the write method to the MTJ element 2, 3 is not limited to the case of varying the write current I_{RL}. The power amount that is supplied to the MTJ elements 1, 2, 3 may be made different between the write to the MTJ element 1 and the write to the MTJ element 2, 3. The power amount, in this context, means the power amount which was substantially supplied to the MTJ elements 1, 2, 3 of the memory cell MC and fuse cell FC, and is determined based on the value and time of the current flowing in the MTJ element 1, 2, 3. Specifically, the write to the MTJ element 2, 3 can be implemented by making the write time longer, aside from increasing the write current I_{RL}.

### (3) Configuration Example and Operation Example of Mode Controller and Circumjacent Circuits Thereof

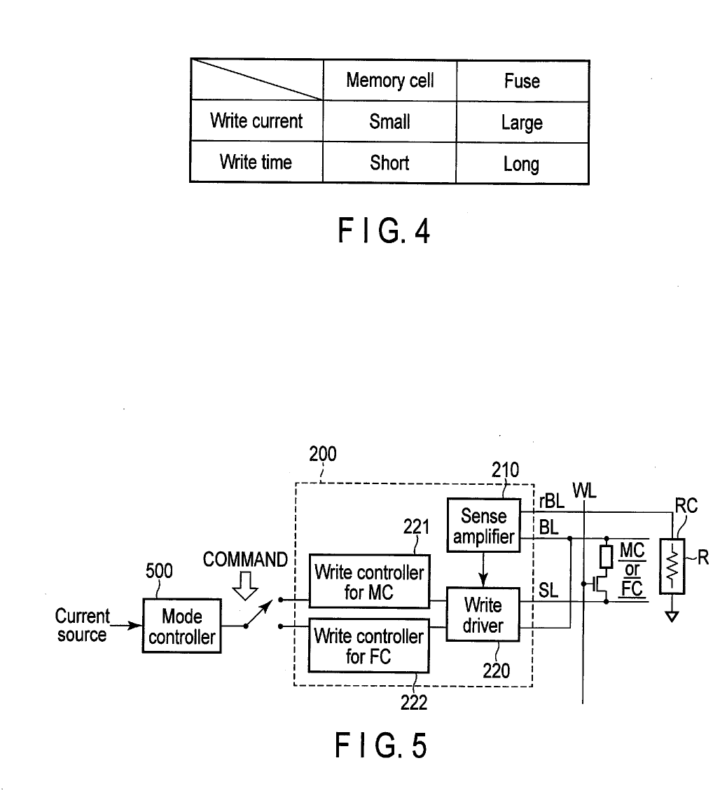

Referring to FIG. 4 and FIG. 5, a description is given of a configuration example and an operation example of the mode controller 500 and circumjacent circuits thereof. FIG. 4 illustrates an example of conditions of write to the memory element which the memory device according to the embodiment includes. FIG. 5 illustrates a configuration example of the mode controller which the memory device according to the embodiment includes, and circumjacent circuits thereof.

As described above, depending on a difference as to whether the write target is the memory cell MC or the fuse cell FC, different power amounts are supplied to the memory cell MC and fuse cell FC. The power amount is varied, for example, by controlling at least either one of the magnitude of the write current and the length of the write time.

As illustrated in FIG. 4, in the present embodiment, both the magnitude of the write current and the write time are different. For example, in the write operation to the memory cell MC, a write current I_{FL} is supplied to the memory cell MC for a write time T_{FL}. The write conditions, under which write is executed by using the write current I_{FL} for the write time T_{FL}, are also called “memory write mode”. In the rewrite operation to the fuse cell FC, a write current I_{RL}, which is greater than the write current I_{FL}, is supplied to the fuse cell FC for a write time T_{RL} which is longer than the write time T_{FL}. The write conditions, under which write is executed by using the write current I_{RL} for the write time T_{RL}, are also called “fuse write mode”.

As illustrated in FIG. 5, the mode controller 500 is disposed on a path between a current source or a voltage source and the RW circuit 200, and is connected to a write controller 221 or a write controller 222 of the RW circuit 200.

The current source or voltage source is disposed in the MRAM 10. Alternatively, a current source or a voltage source, which generates a greater write current I_{RL}, may be provided outside the MRAM 10 as an external unit or the like.

The write controller 221 is a circuit which generates the write current I_{FL} for the write time T_{FL}. The write controller 222 is a circuit which generates the write current I_{RL} for the write time T_{RL}. Alternatively, the write controller 221, 222 may operate to generate the write current I_{FL}, I_{RL} as pulses, so that the total write time becomes the write time T_{FL}, T_{RL}.

Upon receiving a command instructing write to either the memory cell MC or the fuse cell FC, the mode controller 500 switches, where necessary, a connection to the write controller 221 or to the write controller 222. Specifically, upon receiving a command instructing write to the memory cell MC, the mode controller 500 maintains a connection to the write controller 221 or switches a connection to the write controller 221. Upon receiving a command instructing write to the fuse cell FC, the mode controller 500 maintains a connection to the write controller 222 or switches a connection to the write controller 222.

The write current I_{FL}, which the write controller 221 has generated, is supplied by the write driver 220 to the memory cell MC for the write time T_{FL}. The write current I_{RL}, which the write controller 222 has generated, is supplied by the write driver 220 to the fuse cell FC for the write time T_{RL}. At this time, the write driver 220 supplies the write current I_{FL}, I_{RL} to one of the bit line BL and source line SL, and sets the other at a ground potential, and controls the direction in which the write current I_{FL}, I_{RL} flows through the MTJ element 1, 2, 3. Even after the end of the write operation, the mode controller 500 maintains the connection to the write controller 221 or write controller 222 until receiving the next write command.

In this manner, at the time of write to the memory cell MC or fuse cell FC, the mode controller 500 switches the write conditions (write mode), such as the write current I_{FL}, I_{RL} and the write time T_{FL}, T_{RL}, in accordance with the difference of the operation target. Specifically, the different write controllers 221 and 222 are used in different write modes.

On the other hand, at the time of read, the common sense amplifier 210 is used for each of the memory cell MC and fuse cell FC. The data written in the memory cell MC and the information written in the fuse cell FC are properly read out by the sense amplifier 210 and transferred to the comparison circuit 310c.

### (4) Write Operation to Fuse Cell

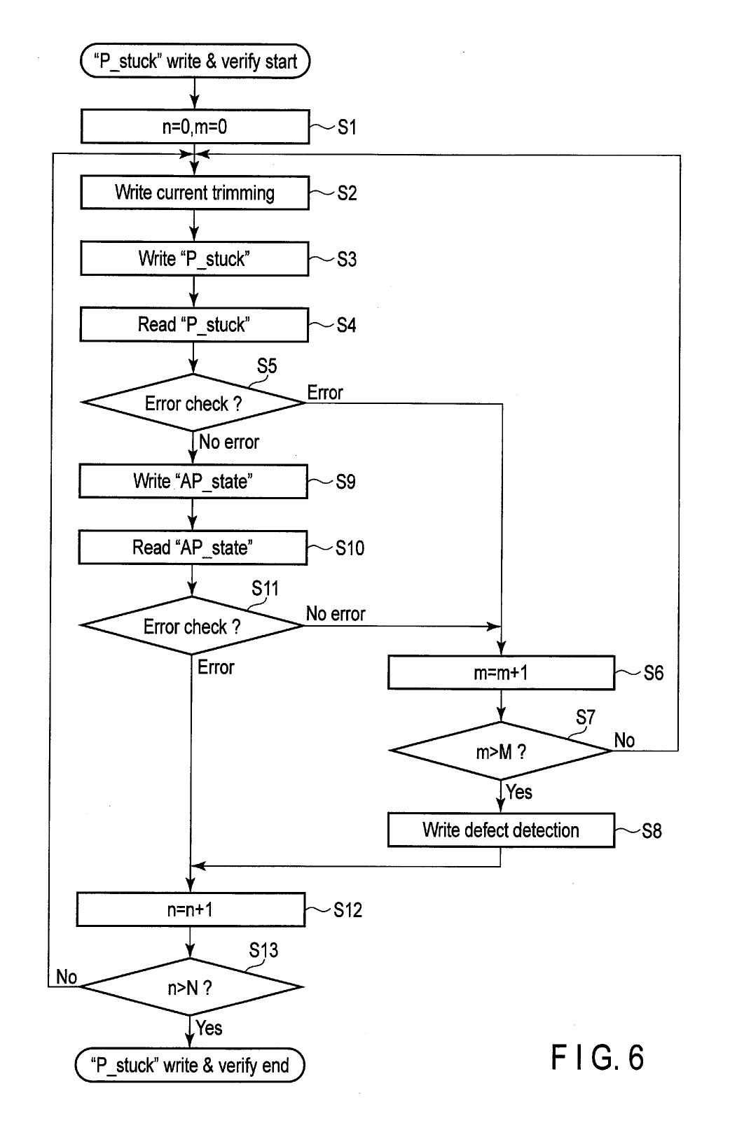

Referring to FIG. 6, an example of a write operation to the fuse cell FC is described. FIG. 6 illustrates a flow of the write operation to the fuse cell which the memory device according to the embodiment includes.

At a final phase of a manufacturing process of the MRAM 10, a non-defective product inspection is performed, for example, for each memory cell MC in the cell array 100. Any one of the memory cells MC of the redundant cell array 100r is assigned for replacement of a memory cell MC which was determined to be defective. In the fuse cell FC, for example, address information relating to the memory cell MC that was determined to be defective, and the memory cell MC of the redundant cell array 100r, with which the memory cell MC determined to be defective is replaced, is programmed.

As described above, initially, the fuse cell FC includes the MTJ element 3, and is configured in the high-resistance state. In the program of the fuse cell FC, P_stuck write is executed for the MTJ element 3 of a certain fuse cell FC, and the MTJ element 3 is rewritten to a low-resistance MTJ element 2. The operation to be described below is mainly performed by the controller 600 which received an instruction from the outside.

As illustrated in FIG. 6, in step S1, the address decoder 300 selects a fuse cell FC with an address number n of 0, from among fuse cells FC for which P_stuck write is to be executed. The controller 600 sets a trimming level number m of a write current I_{RL} at 0. In the write to the fuse cell FC, the write controller 222 increases stepwise the magnitude of the write current I_{RL}. The trimming level number m is a numerical value at a time when each step (trimming level) is numbered. When the trimming level number is 0, the write controller 222 sets the write current I_{RL} to a minimum, and the write controller 222 increases the write current I_{RL} each time the trimming level number increases.

In step S2, the write controller 222 sets the magnitude of the write current I_{RL} in accordance with the trimming level number m. In step S3, by using the write current I_{RL}, the write driver 220 executes P_stuck write to the fuse cell FC of the address number n. In step S4, the sense amplifier 210 reads out the information which was written in the fuse cell FC. In step S5, based on the read-out information, the controller 600 verifies whether the fuse cell FC exhibits a low resistance. If the fuse cell FC exhibits a low resistance, the controller 600 determines that the fuse cell FC has passed verify. If the fuse cell FC remains in a high-resistance state, the controller 600 determines a verify error.

In the case of an error in step S5, an operation of step S6 onwards is performed. In step S6, the controller 600 increments the trimming level number m by 1. In step S7, the controller 600 determines whether the incremented trimming level number m exceeds an upper-limit trimming level number M. The upper-limit trimming level number M is set such that the write current I_{RL} does not exceed a certain value. This value is determined, for example, so that the magnetization direction of the shift cancel layer SCL of the fuse cell FC may not be reversed, or no dielectric breakdown occurs in the fuse cell FC.

Subsequently, the operation of steps S2 to S7 is repeated as needed. If an error is not eliminated in step S5 and the trimming level number m has exceeded the upper-limit trimming level M in step S7, the controller 600 determines a P_stuck write defect in step S8. Thus, the P_stuck write for the fuse cell FC ends in failure. Then, an operation of step S12 onwards is performed.

If an error is eliminated in step S5, it is further confirmed in subsequent steps S9 to S11 whether P_stuck write has correctly been executed. However, steps S9 to S11 are not indispensable.

In step S9, the write controller 221 generates a write current I_{FL} which is used at a write of the MTJ element 1 of the memory cell MC, and the write driver 220 executes, in the fuse cell FC in which the P_stuck write was executed, such write that the magnetization direction of the memory layer FL becomes antiparallel to the magnetization direction of the reference layer RL. In step S10, the sense amplifier 210 reads out information of the fuse cell FC. In step S11, based on the read-out information, the controller 600 verifies whether the fuse cell FC, in which the memory layer FL was made antiparallel, exhibits a high resistance.

In step S5, even if it is confirmed that the fuse cell FC is in a low-resistance state, it is possible that, for example, only the memory layer FL was rewritten and the reference layer RL was not rewritten. In step S11, this can be confirmed by the fact that the fuse cell FC exhibits a high resistance and passes verify. In step S11, if the fuse cell FC remains in a low-resistance state, it can be confirmed in the flow of steps S2 to S7 that the P_stuck write was correctly executed. Accordingly, if the fuse cell FC takes a high-resistance state and passes verify, the controller 600 determines that the P_stuck write is not correctly executed. If the fuse cell FC remains in a low-resistance state and a verify error occurs, the controller 600 determines that the P_stuck write was correctly executed.

If verify is passed in step S11, the operation of step S6 onwards is executed. Then, the operation of steps S2 to S11 is repeated as needed, so that P_stuck write may correctly be executed. By the repetition of this operation, if the trimming level number m exceeds the upper-limit trimming level number M, the controller 600 determines a P_stuck write defect in step S8, and the P_stuck write for the fuse cell FC ends in failure. Then, the operation of step S12 onwards is performed.

If an error is determined in step S11, the controller 600 determines that the P_stuck write was correctly executed, and goes to step S12.

In step S12, the address decoder 300 increments the address number n of the fuse cell FC by 1. In step S13, the controller 600 determines whether the incremented address number n exceeds the last address number N of the fuse cells FC for which P_stuck write is to be executed.

If the incremented address number n does not exceed the last address number N, the operation from step S2 starts for the fuse cell FC of the incremented address number n. If the incremented address number n exceeds the last address number N, the controller 600 determines that P_stuck write has been executed for all fuse cells FC, and ends the P_stuck write.

By the above, the information based on the result of the non-defective product inspection, which is performed at the final phase of the manufacturing process of the MRAM 10, is programmed in the fuse cell FC. Subsequently, if it becomes necessary to rewrite such information, P_stuck write is executed, as needed, for the MTJ element 3 of the fuse cell FC which was not programmed in the above. In addition, in the fuse cell FC which was programmed in the above, the low-resistance MTJ element 2 is rewritten to the high-resistance MTJ element 3, where necessary. In short, rewrite of information, which the fuse cell FC stores, is executed.

When the low-resistance MTJ element 2 is rewritten to the high-resistance MTJ element 3, a write current I_{RL} in an opposite direction to the P_stuck write is used in the above-described step S3 in FIG. 6. In addition, in step S11, the case in which verify was passed is determined to be normal write, and the case in which a verify error occurred is determined to be a write defect. In the case of a write defect, the operation of steps S2 to S11 is repeated as needed. In the meantime, steps S9 to S11 may not be executed.

### (5) Advantageous Effects of Embodiment

According to the embodiment, the following one or plural advantageous effects are obtained.

(A) According to the embodiment, the MTJ element 2, 3 stores information relating to the MTJ element 1. This information is rewritable.

In a fuse circuit of a comparative example, for example, a laser fuse having wiring lines of a metal or polysilicon is used. At a time of program, some wiring lines are blown by a laser blow or the like, and are electrically opened. In this manner, if the fuse circuit of the comparative example is once programmed, rewire of information cannot be executed. In addition, because of the need to execute a laser blow, it is difficult to reduce the pitch of wiring lines.

According to the embodiment, the MTJ element 2, 3, which is used in the fuse cell FC, has the same configuration as the MTJ element 1 which is used in the memory cell MC, and rewrite of information can be executed multiple times. Thus, even after the MRAM 10 is completed as a product, for example, if a new defect occurs due to secular degradation or the like, the information of the fuse cell FC can be rewritten once again. Furthermore, for example, at the time of the manufacture of the MRAM 10, it becomes possible to program the fuse cell FC at a final stage of the front end of the line, and to add information of a defective point, which further occurs, to the fuse cell FC at a final stage of the back end of the line.

Alternatively, according to the embodiment, the size and pitch of MTJ element 2, 3 can be made substantially equal to those of the MTJ elements 1. For example, compared to the fuse circuit of the comparative example, the area occupied by the fuse cells FC can be reduced. In addition, for example, since the MTJ elements 2, 3 and MTJ elements 1 can be formed batchwise, the number of steps in the manufacturing process does not increase.

(B) According to the embodiment, the information which the MTJ element 2, 3 stores is rewritten by a power amount, which is greater than a power amount at a time of write of data in the MTJ element 1, being supplied to the MTJ element 2, 3.

In the fuse circuit of the comparative example, for example, there is a case in which an eFuse including a DRAM (Dynamic Random Access Memory) cell is used. At a time of program, as regards a DRAM cell which is to be electrically opened, a high current or a high voltage is applied to the DRAM cell, and dielectric breakdown is caused to occur in the DRAM cell. Thereby, a risk of rewrite of information lowers, unlike normal write to a DRAM cell. However, in this case, too, like the above, the fuse circuit of the comparative example, once programmed, cannot execute rewrite of information.

According to the embodiment, at a time of rewrite of information, the power amount, which is greater than the power amount at a time of write of data in the MTJ element 1, is supplied to the MTJ element 2, 3. However, this power amount is not such a power amount as to cause, for example, dielectric breakdown. Specifically, the information of the MTJ element 2, 3 can be rewritten by reversing the magnetization direction of the reference layer RL. Thereby, while suppressing easy rewrite of information, the MTJ element 2, 3 can be kept in a state in which information is still rewritable.

(C) According to the embodiment, in the MTJ element 2, the magnetization direction of the reference layer RL and the magnetization direction of the shift cancel layer SCL are parallel. In the MTJ element 3, the magnetization direction of the reference layer RL and the magnetization direction of the shift cancel layer SCL are antiparallel.

Thereby, information pieces of two values of a low resistance and a high resistance can be stored by the MTJ element 2 and MTJ element 3.

Alternatively, compared to the memory layer FL, it is not easy to reverse the magnetization direction of the reference layer RL. Further, in the MTJ element 2, rewrite of the magnetization direction of the memory layer FL is difficult. Thus, the MTJ element 2 can store information more stably.

(D) According to the embodiment, the MRAM 10 switches, by the mode controller 500, the write operation to the memory cell MC and the write operation to the fuse cell FC. Thereby, the write conditions of short time and low current can be applied to the memory cell MC. Thus, without lowering the write performance to the memory cell MC, the write to the fuse cell FC can be executed.

(E) According to the embodiment, at a time of P_stuck write to the fuse cell FC, steps S9 to S11 of FIG. 6 are executed. Thereby, it is more exactly confirmed whether P_stuck write was correctly executed.

### OTHER EMBODIMENTS

In the above embodiment, the description has been given of the example in which the MTJ elements 2, 3 are used as the fuse cells FC, but the embodiment is not limited to this. These MTJ elements can also be used as, for instance, memory elements of an OTP (one time program) area. In this case, these MTJ elements can store, as information, flag data which protects, for example, security data. A memory cell MC in which a flag is set up is deemed to be a memory cell MC which stores security data, and access to this memory cell MC is limited. Specifically, such a memory cell MC can be configured such that read is disabled, or read cannot be executed unless by a special command.

In the above-described embodiment, the description has been given of the example in which both the write current and the write time are made different in the write conditions of the MTJ elements 1, 2, 3, but the embodiment is not limited to this. Either the write current or the write time may be made different for these MTJ elements. Thereby, the power amounts which are supplied to these MTJ elements can be made different.

In the above-described embodiment, the description has been given of the example in which the MTJ element 1, 2, 3 includes the memory layer FL, middle layer ML, reference layer RL and shift cancel layer SCL, but the embodiment is not limited to this. These MTJ elements may include layers other than the above-described layers. For example, these MTJ elements may include a spacer layer between the reference layer and the shift cancel layer. The spacer layer has a function of suppressing ferromagnetic coupling between the reference layer and the shift cancel layer.

In the above-described embodiment, the description has been given of the example in which the MTJ elements 1, 2, 3 are bottom free type (top pin type) MTJ elements in which the memory layer is disposed below the reference layer, but the embodiment is not limited to this. These MTJ elements may be top free type (bottom pin type) MTJ elements in which the memory layer is disposed above the reference layer. Alternatively, the shift cancel layer may be disposed on the memory layer side, for example, between the memory layer and electrode.

In the above-described embodiment, the description has been given of the example in which the MTJ elements 1, 2, 3 are vertical-magnetization MTJ elements, but the embodiment is not limited to this. These MTJ elements may be horizontal-magnetization MTJ elements each having a horizontal magnetic anisotropy. In this case, each layer of the MTJ element has a magnetization direction along the layer surface. The direction along the layer surface is a direction which is horizontal, or substantially horizontal, to the layer surface.

When the MTJ element is a horizontal-magnetization MTJ element, the magnitude of coercivity in each layer of the MTJ element may be adjusted by the width in the magnetization direction along the layer surface of each layer. Specifically, the widths of the respective layers are adjusted such that the width of the reference layer RL is greater than the width of the memory layer FL, and the width of the shift cancel layer SCL is greater than the width of the reference layer RL. In the vertical-magnetization MTJ element, the coercivities of the respective layers FL, RL and SCL may be adjusted by the areas in a direction along the layer surfaces of the respective layers FL, RL and SCL.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A memory device comprising:
a first memory element being able to store data; and
a second memory element storing information relating to the first memory element,
wherein the information is rewritten by a power amount, which is greater than a power amount at a time when the data is written in the first memory element, being supplied to the second memory element.

2. The memory device of claim 1,
wherein each of the first memory element and the second memory element is a magnetoresistive effect element including;
a memory layer with a first coercivity and
a reference layer with a second coercivity which is greater than the first coercivity,
the data is written by reversing a magnetization direction of the memory layer of the first memory element, and
the information is rewritten by reversing a magnetization direction of the reference layer of the second memory element.

3. The memory device of claim 1,
wherein each of the first memory element and the second memory element is a magnetoresistive effect element including;
a memory layer with a first coercivity,
a reference layer with a second coercivity which is greater than the first coercivity, and
a shift cancel layer with a third coercivity which is greater than the second coercivity,
a magnetization direction of the reference layer and a magnetization direction of the shift cancel layer are antiparallel in the first memory element, and
a magnetization direction of the reference layer and a magnetization direction of the shift cancel layer are parallel or antiparallel in the second memory element.

4. The memory device of claim 3,
wherein the first memory element stores the data by a magnetization direction of the memory layer and the magnetization direction of the reference layer being made parallel or antiparallel, and
the second memory element stores the information by the magnetization direction of the reference layer and the magnetization direction of the shift cancel layer being made parallel or antiparallel.

5. The memory device of claim 1, wherein the information is rewritten by a write current, which is greater than a write current at a time when the data is written in the first memory element, being caused to flow through the second memory element.

6. The memory device of claim 1, wherein the information is rewritten by a write current being caused to flow through the second memory element for a longer time than a time of a write current flowing when the data is written in the first memory element.

7. The memory device of claim 1, wherein the second memory element is included in a fuse circuit.

8. The memory device of claim 7, wherein the information relating to the first memory element is address information of the first memory element with a defect.

9. The memory device of claim 7, further comprising:
a cell array including the first memory element; and
a redundant cell array including the first memory element with which the first memory element of the cell array is replaceable,
wherein the information relating to the first memory element is address information of the first memory element of the cell array, which is replaced with the first memory element of the redundant cell array.

10. The memory device of claim 1, wherein the second memory element is included in a One Time Program (OTP) area.

11. A memory device comprising:
a first magnetoresistive effect element being able to store data; and
a second magnetoresistive effect element storing information relating to the first magnetoresistive effect element,
wherein each of the first magnetoresistive effect element and the second magnetoresistive effect element includes;
a memory layer with a first coercivity,
a reference layer with a second coercivity which is greater than the first coercivity, and
a shift cancel layer with a third coercivity which is greater than the second coercivity,
a magnetization direction of the reference layer and a magnetization direction of the shift cancel layer are antiparallel in the first magnetoresistive effect element, and
a magnetization direction of the reference layer and a magnetization direction of the shift cancel layer are parallel in the second magnetoresistive effect element.

12. The memory device of claim 11, further comprising a third magnetoresistive effect element storing information relating to the first magnetoresistive effect element,
wherein the third magnetoresistive effect element includes;
a memory layer with the first coercivity,
a reference layer with the second coercivity, and
a shift cancel layer with the third coercivity, and
a magnetization direction of the reference layer and a magnetization direction of the shift cancel layer are antiparallel in the third magnetoresistive effect element.

13. The memory device of claim 11,
wherein the data is written by reversing a magnetization direction of the memory layer of the first magnetoresistive effect element, and
the information is rewritten by reversing the magnetization direction of the reference layer of the second magnetoresistive effect element.

14. The memory device of claim 11, wherein the information is rewritten by a power amount, which is greater than a power amount at a time when the data is written in the first magnetoresistive effect element, being supplied to the second magnetoresistive effect element.

15. The memory device of claim 11, wherein the information is rewritten by a write current, which is greater than a write current at a time when the data is written in the first magnetoresistive effect element, being caused to flow through the second magnetoresistive effect element.

16. The memory device of claim 11, wherein the information is rewritten by a write current being caused to flow through the second magnetoresistive effect element for a longer time than a time of a write current flowing when the data is written in the first magnetoresistive effect element.

17. The memory device of claim 11, wherein the second magnetoresistive effect element is included in a fuse circuit.

18. The memory device of claim 17, wherein the information relating to the first magnetoresistive effect element is address information of the first magnetoresistive effect element with a defect.

19. The memory device of claim 17, further comprising:
a cell array including the first magnetoresistive effect element; and
a redundant cell array including the first magnetoresistive effect element with which the first magnetoresistive effect element of the cell array is replaceable,
wherein the information relating to the first magnetoresistive effect element is address information of the first magnetoresistive effect element of the cell array, which is replaced with the first magnetoresistive effect element of the redundant cell array.

20. The memory device of claim 11, wherein the second magnetoresistive effect element is included in a One Time Program (OTP) area.
